(19) United States
(12) Patent Application Publication
(10) Pub. No.: US 2007/0176287 A1
(43) Pub. Date: Aug. 2, 2007

(54) Thin integrated circuit device packages for improved radio frequency performance

(76) Inventors: Sean T. Crowley, Phoenix, AZ (US); Ludovico E. Bancod, Chandler, AZ (US); Terry Davis, Gilbert, AZ (US); Robert F. Darveaux, Higley, AZ (US); Michael P. Gaynor, Chandler, AZ (US)

Correspondence Address: STETINA BRUNDA GARRED & BRUCKER, 75 ENTERPRISE, SUITE 250, ALISO VIEJO, CA, 92656, US

(21) Appl. No.: 10/812,274

(22) Filed: Mar. 29, 2004

Related U.S. Application Data
(63) Continuation-in-part of application No. 10/667,759, filed on Sep. 22, 2003, now abandoned.
Application No. 10/667,759 is a continuation-in-part of application No. 10/354,772, filed on Jan. 30, 2003, now Pat. No. 6,833,609.
Application No. 10/354,772 is a continuation of application No. 09/434,589, filed on Nov. 5, 1999, now Pat. No. 6,580,159.

(51) Int. Cl. H01L 23/34

(52) U.S. Cl. 257/728

(57) ABSTRACT

A semiconductor package comprising a non-conductive film which defines opposed top and bottom film surfaces and includes a plurality of vias disposed therein. Disposed on the top film surface is a plurality of upper leads which circumvent respective ones of the vias. Similarly, disposed on the bottom film surface is a plurality of lower leads which circumvent respective ones of the vias and are electrically connected to respective ones of the upper leads. At least one transmission line element is also disposed on the top film surface and electrically connected to at least one of the upper leads. Attached to the top film surface and electrically connected to at least one of the upper leads and the transmission line element is at least one semiconductor die. A package body at least partially covers the semiconductor die, the upper leads, the transmission line element, and the top film surface.

### CROSS-REFERENCE TO RELATED APPLICATIONS

The present application is a continuation-in-part of U.S. application Ser. No. 10/667,759 entitled METHODS OF MAKING THIN INTEGRATED CIRCUIT DEVICE PACKAGES WITH IMPROVED THERMAL PERFORMANCE AND INCREASED I/O DENSITY filed Sep. 22, 2003, which is a continuation-in-part of U.S. application Ser. No. 10/354,772 entitled INTEGRATED CIRCUIT DEVICE PACKAGES AND SUBSTRATES FOR MAKING THE PACKAGES filed Jan. 30, 2003, which is a continuation of U.S. application Ser. No. 09/434,589 entitled INTEGRATED CIRCUIT DEVICE PACKAGES AND SUBSTRATES FOR MAKING THE PACKAGES filed Nov. 5, 1999 and issued as U.S. Pat. No. 6,580,159 on Jun. 17, 2003, the disclosures of which are incorporated herein by reference.

### STATEMENT RE: FEDERALLY SPONSORED RESEARCH/DEVELOPMENT

Not Applicable

### BACKGROUND OF THE INVENTION

The present invention relates generally to plastic semiconductor packages, and more particularly, to a semiconductor package adapted for improved radio frequency performance through the integration of one or more transmission line elements.

As is well known in the electrical arts, recently industry trends in wireless communications are driving increased integration, size reduction, and cost reduction. In this regard, many radio frequency (RF) circuits require matching, filtering and biasing networks, which in turn require inductors having relatively high inductance values with low loss. In addition to inductors, many radio frequency circuits require other transmission line elements such as filters, baluns and couplers.

In an attempt to satisfy the need for implementing and integrating inductors into semiconductor packages, there has been developed in the prior art methods for forming inductors in leadframes for semiconductor packages. However, a major drawback associated with currently known leadframe based inductors for semiconductor packages such as RF modules is that such packages are limited to gross lines and pitches, typically on the order of six mil lines on six mil spaces. As a result, the number of inductors or other transmission line elements that can be incorporated into the finished semiconductor package are extremely limited.

The present invention addresses this deficiency by providing a tape based semiconductor package or RF module wherein a two or three layer tape substrate is used in order to increase the density of the components that can be integrated into the semiconductor package. The use of the two or three layer tape allows fine lines and pitches to be utilized in the semiconductor package or RF module design, which in turn allows for the integration into the package of all the transmission line elements that may be desired for the package. In addition to inductors, these transmission line elements include baluns, filters and couplers. As indicated above, because the semiconductor package or RF module of the present invention is tape based, finer lines and pitches can be obtained in comparison to leadframe based semiconductor packages including inductors. In this regard, the tape based semiconductor package or RF module of the present invention typically has one mil lines on one mil spaces, a significant improvement over the aforementioned six mil lines on six mil spaces typically found in comparable leadframe based packages. As also indicated above, because of the fine pitch and spaces inherent in the tape based package of the present invention, many other transmission line elements can be incorporated into the finished package. As such, the present invention provides a cost-effective technique for implementing and integrating inductors and other transmission line elements into semiconductor packages or RF modules. These, as well as other features and advantages of the present invention, will be described in more detail below.

### BRIEF SUMMARY OF THE INVENTION

In accordance with the present invention, there is provided a semiconductor package or RF module which is adapted to provide improved radio frequency performance through the integration of one or more transmission line elements. The semiconductor package of the present invention has a tape based construction, which allows for the implementation of the fine pitches and spaces needed to allow for the integration of one or more transmission line elements such as inductors, shortwave couplers, baluns and filters into the semiconductor package. In such tape based construction, metal layers are applied to each of the opposed sides or faces of a non-conductive film, with a subtractive or additive method thereafter being employed to facilitate the formation of leads and transmission line elements upon the film in any one of a variety of different configurations. Thus, the present invention represents a substantial departure from and provides significant advantages over leadframe based inductors for semiconductor packages which, due to their comparatively gross pitches and spaces, provide substantially less design flexibility.

The present invention is best understood by reference to the following detailed description when read in conjunction with the accompanying drawings.

### BRIEF DESCRIPTION OF THE DRAWINGS

These, as well as other features of the present invention, will become more apparent upon reference to the drawings wherein:

FIG. 1 is a top plan view of a semiconductor package or RF module constructed in accordance with the present invention, a portion of the package body of the semiconductor package being removed for purposes of exposing the internal film layer and elements formed thereon;

FIG. 2 is a bottom plan view of the semiconductor package shown in FIG. 1; and

FIG. 3 is a cross-sectional view of the semiconductor package of the present invention taken along line 3-3 of FIG. 1.

Common reference numerals are used throughout the drawings and detailed description to indicate like elements.

### DETAILED DESCRIPTION OF THE INVENTION

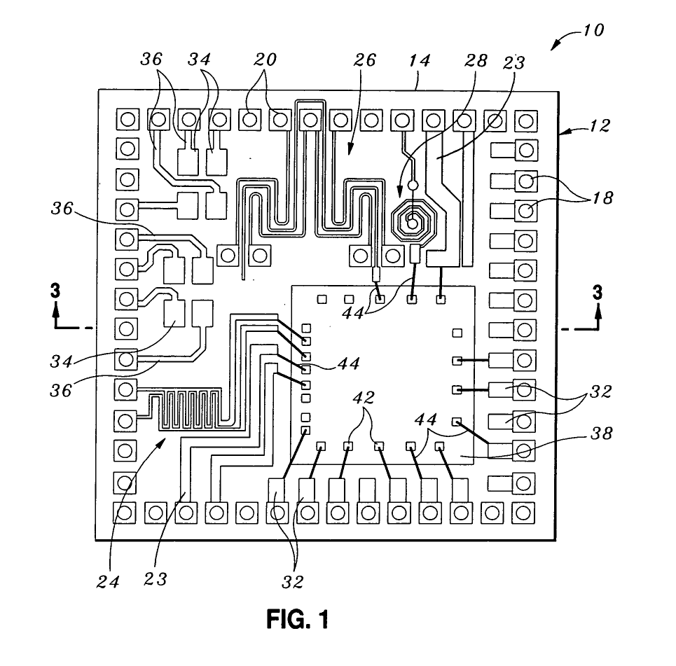

Referring now to the drawings wherein the showings are for purposes of illustrating a preferred embodiment of the present invention only, and not for purposes of limiting the same, FIGS. 1-3 depict a semiconductor package 10 constructed in accordance with the present invention. As will be described in more detail below, the semiconductor package 10 is outfitted with structural elements which make the same uniquely suited for use as a radio frequency (RF) module. However, those of ordinary skill in the art will recognize that the manufacturing methodology for the semiconductor package 10 which will be described in more detail below is also applicable to semiconductor packages having configurations adapted for use in applications other than as an RF module.

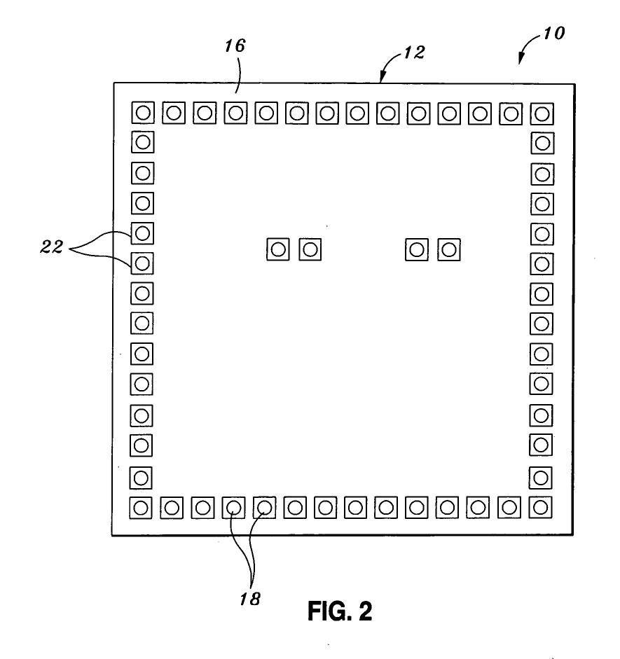

The semiconductor package 10 comprises a tape or film layer 12 which defines a generally planar top surface 14 and an opposed, generally planar bottom surface 16. In this regard, the film layer 12 is a generally planar sheet which is fabricated from a non-conductive material. By way of example, the film layer 12 may be fabricated from a polyimide film having a thickness of approximately 50 microns. Alternatively, the film layer 12 may be formed of a fiber-reinforced epoxy laminate, woven aramid, BT laminate, or other plastic material. As shown in FIGS. 1 and 2, the film layer 12 has a generally quadrangular (i.e., square) configuration. Disposed within the film layer 12 are a plurality of openings or vias 18 which extend between the top and bottom surfaces 14, 16 thereof. The vias 18 are segregated into an outer set and an inner set. The vias 18 of the outer set are arranged in a generally square pattern extending along and in relative close proximity to the peripheral edge of the film layer 12. The vias 18 of the inner set, which are optional as will be discussed in more detail below, are included in a central portion of the film layer 12.

In addition to the film layer 12, the semiconductor package 10 comprises a plurality of upper leads 20 which are disposed on the top surface 14 of the film layer 12. As best seen in FIG. 1, each of the upper leads 20 is formed on the top surface 14 so as to extend about or circumvent a respective one of the vias 18 of the inner and outer sets thereof. Though each of the upper leads 20 is depicted as having a generally quadrangular (i.e., square) configuration, those of ordinary skill in the art will recognize that alternative configurations for the upper leads 20 are contemplated herein.

Disposed on the bottom surface 16 of the film layer 12 are a plurality of lower leads 22. Like the upper leads 20, each of the lower leads 22 is oriented on the bottom surface 16 so as to circumvent a respective one of the vias 18 of the inner and outer sets thereof. As shown in FIG. 2, each of the lower leads 22 also has a generally quadrangular (i.e., square) configuration, though alternative configurations are also contemplated in relation thereto. In the semiconductor package 10, both the upper leads 20 and lower leads 22 are each fabricated from a conductive metal material such as copper, in a manner which will be described in more detail below. Those upper leads 20 circumventing the vias 18 of the outer set constitute an outer set of upper leads 20, with those upper leads 20 circumventing the vias 18 of the inner set constituting an inner set of upper leads 20. The height or thickness of the upper leads 20 is preferably substantially equal to that of the lower leads 22. However, those of ordinary skill in the art will recognize that the thicknesses of the upper and lower leads 20, 22 need not necessarily be equal.

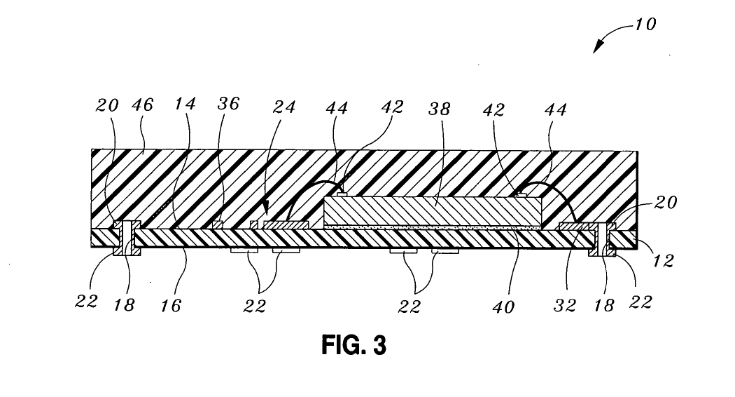

As best seen in FIG. 3, in the semiconductor package 10, each of the upper leads 20 is conductively or electrically connected to a respective one of the lower leads 22. Such electrical connection is preferably facilitated by a conductive plating layer which lines each via 18 and extends between the upper and lower leads 20, 22 of the corresponding pair. Though not shown, as an alternative to being lined with a layer of conductive metal material, each via 18 may be completely filled with such material to facilitate the electrical connection of the upper leads 20 to respective ones of the lower leads 22. As will be recognized, if each via 18 were to be completely filled with the conductive metal material as opposed to simply being lined therewith, the outermost surface of each of the upper leads 20 as shown in FIG. 1 and the outermost surface of each of the lower leads 22 as shown in FIG. 2 would be substantially continuous, as opposed to one of the vias 18 being observable therein.

Referring now to FIGS. 1 and 3, also formed on the top surface 14 of the film layer 12 are a plurality of transition line elements. These transition line elements include a shortwave coupler 24, a balun 26, and a spiral inductor 28. Other elements formed on the top surface 14 include large busses 23. Though not shown in FIGS. 1 and 3, a further transmission line element that may be integrated into the semiconductor package 10 as a replacement to any one of the aforementioned transmission line elements is a filter. Like the upper and lower leads 20, 22 described above, each of the aforementioned transmission line elements is fabricated from a conductive metal material such as copper. As further seen in FIG. 1, each of the transmission line elements is electrically connected to one or more of the upper leads 20. For example, the shortwave coupler 24 is electrically connected to an adjacent pair of the upper leads 20 of the outer set. The balun 26 is electrically connected to three adjacent upper leads 20 of the outer set, in addition to all of the upper leads 20 of the inner set. As seen in FIG. 3, the transmission line elements are each preferably formed to be of a height or thickness substantially equal to that of the upper leads 20. However, those of ordinary skill in the art will recognize that the thicknesses of the transmission line elements need not necessarily be identical to that of the upper leads 20. It is contemplated that any of the transmission line elements included in the semiconductor package 10 may be selectively “tuned” by varying the dimensions thereof.

In addition to the above-described transmission line elements, also formed on the top surface 14 of the film layer 12 are a plurality of conductive traces 32 which are electrically connected to and extend inwardly from certain ones of the upper leads 20. Each of the traces 32 is also fabricated from a conductive metal material such as copper. Though the traces 32 are shown in FIGS. 1 and 3 as being of a height or thickness substantially equal to that of the upper leads 20, those of ordinary skill in the art will recognize that the traces 32 and upper leads 20 may be of differing thicknesses.

Also formed on the top surface 14 of the film layer 12 is a plurality of terminals or pads 34. Each of the pads 34 is electrically connected to a respective one of the upper leads 20 by an elongate conductive trace 36. The pads 34 as shown in FIG. 1 are segregated into two sets or groups of four pads 34 each. The pads 34 and traces 36 are also each preferably fabricated from a conductive metal material such as copper. Additionally, the height or thicknesses of the pads 34 and traces 36 is preferably equal to that of the upper leads 20, though those of ordinary skill in the art will recognize that the pads 34, traces 36 and upper leads 20 may be formed so as to be of differing thicknesses. The use of the pads 34 of each set will be described in more detail below.

The semiconductor package 10 further includes an integrated circuit device or semiconductor die 38 which is attached to a portion of the top surface 14 of the film layer 12. More particularly, the semiconductor die 38 is attached to a generally quadrangular (i.e., square) portion of the top surface 14 which is defined by portions of the transmission line elements and traces 32. The attachment of the semiconductor die 38 to the top surface 14 of the film layer 12 is preferably accomplished through the use of a layer 40 of a suitable adhesive. As seen in FIGS. 1 and 3, the contacts or terminals 42 of the semiconductor die 38 are electrically connected to each of the transmission line elements and to certain ones of the traces 32 through the use of elongate, conductive bond wires 44. Though not shown, it is contemplated that as an alternative to being adhered directly to the top surface 14 of the film layer 12, the semiconductor die 38 may be adhered to a die pad which is formed on the top surface 14 of the film layer 12 in the above-described quadrangular space adapted to accommodate semiconductor die 38. Such die pad, if included, may optionally be formed such that a surface thereof is also exposed in the bottom surface 16 of the film layer 12. It is also contemplated that a flip chip bonding technique may be employed for the semiconductor die 38 as an alternative to the use of the bond wires 44.

In the semiconductor package 10, the semiconductor die 38, bond wires 44, transmission line elements, traces 32, 36, pads 34, upper leads 20, and the exposed portions of the top surface 14 of the film layer 12 are covered by a package body 46 of the semiconductor package 10. The package body 46 has a generally square configuration, and defines a generally planar top surface and four generally planar side surfaces. The bottom surface of the package body 46 is predominantly covered by the film layer 12. The package body 46 is typically fabricated from a plastic material (e.g., thermosets) via a molding process. In the completed semiconductor package 10, the outermost, bottom surfaces of the lower leads 22 extend in generally co-planar relation to each other along a plane which is generally parallel to and spaced outwardly from the plane defined by the bottom surface 16 of the film layer 12.

Having thus described the structural attributes of the semiconductor package 10 of the present invention, an exemplary method for fabricating the same will now be described. In the initial step of the fabrication method, an unpatterned, non-conductive sheet is provided which will eventually form the film layer 12. Thus, the non-conductive sheet is fabricated from the same material described above in relation to the film layer 12. The non-conductive sheet is subjected to a drilling process wherein the vias 18 of the outer set and the vias 18 of the inner set (if any) are drilled therein. It is contemplated that a laser will be used to drill the vias 18 into the non-conductive sheet, though alternative drilling methods are contemplated to be within the spirit and scope of the present invention. The completion of the drilling operation upon the non-conductive sheet facilitates the completion of the film layer 12.

In the next step of the fabrication process, the film layer 12 is metalized. More particularly, both the top and bottom surfaces 14, 16 of the film layer 12 are plated with a conductive metal material. Such conductive metal material, which is preferably copper, is also plated to those surfaces of the film layer 12 defining the vias 18. As indicated above, rather than the vias 18 simply being lined with the metal material, the vias 18 may be completely filled therewith. The plating of the top and bottom surfaces 14, 16 of the film layer 12 may be conducted simultaneously, or one at a time. The metal layers may be deposited on the top and bottom surfaces 14, 16 of the film layer 12 using a sputtering or other metal deposition process. Alternatively, the metal layers may comprise metal sheets which are mechanically attached to respective ones of the top and bottom surfaces 14, 16 through the use of an adhesive.

Subsequent to the application of the unpatterned metal layers to each of the top and bottom surfaces 14, 16 of the film layer 12, the metal layer applied to the top surface 14 is patterned to facilitate the formation of the upper leads 20, transmission line elements, traces 32, 36, and pads 34. Similarly, the metal layer applied to the bottom surface 16 of the film layer 12 is patterned to facilitate the formation of the lower leads 22. The patterning of each metal layer is preferably performed through the use of a conventional chemical etching process. In this process, a layer of photoresist is applied to each metal layer. The photoresist is exposed to light and developed, thereby forming a patterned mask of photoresist material on the corresponding metal layer. Next, a liquid etchant is applied, the etchant dissolving the metal that is not protected by the photoresist, thus transferring the photoresist mask pattern to the metal layer. Thereafter, the photoresist mask is removed. This process is a subtractive method in that those portions of each metal layer which do not ultimately form one of the above-described elements are simply etched away, thus exposing the underlying film layer. 12.

It is contemplated that as an alternative to the implementation of this subtractive method, an additive method may be implemented to facilitate the formation of these various elements. In accordance with such additive method, a layer of seed metal is applied to both the top and bottom surfaces 14, 16 of the film layer 12, much in the same manner the metal layers are initially applied thereto in the above-described subtractive method. Subsequent to the deposition of such seed metal, a plate-up process is completed in certain areas of each seed metal layer. More particularly, the plate-up is completed in a manner facilitating the formation of the upper leads 20, transmission line elements, traces 32, 36, pads 34, and lower leads 22. Upon the completion of such plate-up process as completely forms these particular elements, the exposed, remaining area of each seed or base metal layer is removed, thus effectively electrically isolating the plated-up elements from each other.

Subsequent to the formation of the upper and lower leads 20, 22, transmission line elements, traces 32, 36 and pads 34 by either the above-described subtracted method or additive method, each such element is preferably plated. Since each of these elements is preferably fabricated from copper, a typical plating metal for such copper is nickel/gold. In the case of those elements formed on the top surface 14 of the film layer 12 (i.e., the upper leads 20, transmission line elements, traces 32, 36 and pads 34), the nickel/gold plating applied thereto enhances the connection of the bond wires 44 to such elements. In the case of the lower leads 22, the nickel/gold plating applied thereto enhances the ability to electrically connect the lower leads 22 to an underlying substrate such as a printed circuit board through the use of conductive connectors such as solder bumps.

Upon the complete formation of the above-described elements on respective ones of the top and bottom surfaces 14, 16 of the film layer 12, the semiconductor die 38 is attached to the aforementioned exposed portion of the top surface 14 of the film layer 12 through the use of the above-described adhesive layer 40. Thereafter, the bond wires 44 are used to electrically connect respective ones of the terminals 42 included on the top surface of the semiconductor die 38 to one or more of the transmission line elements and traces 32. Subsequent to the electrical connection of the semiconductor die 38 to one or more of the transmission line elements and/or one or more of the traces 32, the aforementioned molding process is implemented to facilitate the formation of the package body 46. The formation of the package body 46 completes the fabrication process associated with the semiconductor package 10.

Numerous variants of the configuration of the semiconductor package 10 shown in FIGS. 1, 2, and 3 are within the spirit and scope of the present invention. For example, each of the above-described transmission line elements (e.g., the shortwave coupler 24, balun 26, spiral inductor 28 or filter) need not necessarily be included in the semiconductor package 10. In this regard, such transmission line elements may be included in the semiconductor package 10 individually or in any combination. Further, the pads 34 and corresponding traces 36 need not necessarily be included in the semiconductor package 10. If such pads 34 and corresponding traces 36 are included as in the case of the semiconductor package 10 shown in FIG. 1, it is contemplated that each group or set of the pads 34 may have a discrete, passive element electrically connected thereto. Along these lines, though two sets of four pads 34 are depicted in FIG. 1, it is contemplated that greater or fewer sets of greater or fewer pads 34 may be formed upon the top surface 14 of the film layer 12. Still further, the vias 18 of the inner set and hence the upper and lower leads 20, 22 of the inner sets may be completely eliminated, depending on the number and arrangement of transmission line elements formed on the top surface 14 of the film layer 12. In sum, the size, number, variety, and arrangement of elements on the top and bottom surfaces 14, 16 of the film layer 12 as shown in FIGS. 1 and 2 is exemplary only, the present invention providing the ability to include these elements in any one of a multiplicity of different combinations due to the tape based construction described herein.

With particular regard to the various transmission line elements which may be integrated into the semiconductor package 10, a hexagonal implementation for the spiral inductor 28 is shown in FIG. 1. Those of ordinary skill in the art will recognize that the geometry for the spiral inductor 28 can be anything between a square and a circle. Additionally, the crossover of the spiral inductor 28 may be fabricated as an additional layer. Such fabrication technique would eliminate the inclusion of a bond wire in a spiral conductor 28. The balun 26 consists of only edge couple transmission line structures. The fine line and space geometry facilitated by the fabrication process of the present invention allows for a wider differential impedance range and lower insertion loss. The meander structure also allows for a compact size while sacrificing very little in RF performance. Additionally, the design of the shortwave coupler 24 in accordance with the present invention decreases the size of the traditional quarter wavelength coupler by approximately 70%. The added interdigital capacitor provides for similar RF performance to a traditional coupler. This capacitor can be interdigital as shown or any other capacitor method (MOSCAP, lumped element, silicone implantation, etc.). In addition, if a filter is integrated into the semiconductor package 10, the tape based construction of the semiconductor package 10 allows for the implementation of a traditional lumped element filter design, and for the design of parallel plate low value capacitors. It is contemplated that one or all of the lumped elements can be replaced with distributed elements for a hybrid approach. As previously explained, the ability to include these various transmission line elements in the semiconductor package 10 in any combination is made possible by the tape based construction thereof due to the fine pitch and spaces achievable through such construction. This represents a substantial departure from and improvement over leadframe based inductors for semiconductor packages which, due to the comparatively gross pitch and spaces, are substantially more restricted in terms of design flexibility as it relates to the integration of transmission line elements.

This disclosure provides exemplary embodiments of the present invention. The scope of the present invention is not limited by these exemplary embodiments. Numerous variations, whether explicitly provided for by the specification or implied by the specification such as variations in structure, dimension, type of material and manufacturing process may be implemented by one of skill in the art in view of this disclosure.

1. A semiconductor package comprising:
a single non-conductive film layer defining opposed top and bottom film surfaces and a peripheral edge, the film layer including a plurality of vias disposed therein;
a plurality of upper leads disposed on the top film surface adjacent respective ones of the vias;
a plurality of lower leads disposed on the bottom film surface adjacent respective ones of the vias, each of the lower leads being electrically connected to a respective one of the upper leads;
at least one transmission line element disposed on the top film surface and electrically connected to at least one of the upper leads;
at least one semiconductor die attached to the top film surface and electrically connected to at least one of the upper leads and the transmission line element; and
a package body disposed on the film layer and extending to the peripheral edge thereof, the package body encapsulating the semiconductor die, the upper leads, and the transmission line element, and being adhered to the top film surface.

2. The semiconductor package of claim 1 comprising a plurality of transmission line elements disposed on the top film surface, the semiconductor die being electrically connected to at least one of the transmission line elements.

3. The semiconductor package of claim 2 wherein the transmission line elements are selected from the group consisting of:
an inductor;
a shortwave coupler;
a balun;
a filter; and
combinations thereof.

4. The semiconductor package of claim 1 wherein the upper and lower leads and the transmission line element each include a nickel/gold layer plated thereon.

5. The semiconductor package of claim 1 wherein the semiconductor die is electrically connected to the upper lead and to the transmission line element by respective ones of a plurality of bond wires which are each covered by the package body.

6. The semiconductor package of claim 5 wherein at least some of the upper leads each include a conductive trace connected thereto and extending therefrom, the bond wires being used to electrically connect the semiconductor die to at least one of the traces.

7. The semiconductor package of claim 1 further comprising a plurality of pads disposed on the top film surface and electrically connected to respective ones of the upper leads, the pads being arranged in at least one set which is configured to accommodate a passive device.

8. The semiconductor package of claim 7 wherein the pads are arranged in multiple sets, each of the sets being configured to accommodate a passive device.

9. The semiconductor package of claim 1 wherein the vias are segregated into an outer set which extends along and in relative close proximity to a peripheral edge of the non-conductive sheet, and an inner set which is disposed within the outer set.

10. The semiconductor package of claim 1 wherein the non-conductive sheet is fabricated from a polyimide film.

11. The semiconductor package of claim 1 wherein each of the vias is lined with a conductive metal material to facilitate the electrical connection of the upper leads to respective ones of the lower leads.

12. The semiconductor package of claim 1 wherein each of the vias is filled with a conductive metal material to facilitate the electrical connection of the upper leads to respective ones of the lower leads.

13. A semiconductor package, comprising:
a single non-conductive film layer defining opposed top and bottom film surfaces and a plurality of peripheral film side surfaces, the film layer including a plurality of vias disposed therein;
a plurality of upper leads disposed on the top film surface adjacent respective ones of the vias;
a plurality of lower leads disposed on the bottom film surface adjacent respective ones of the vias, each of the lower leads being electrically connected to a respective one of the upper leads;
a plurality of transmission line elements disposed on the top film surface and electrically connected to at least one of the upper leads; and
a package body encapsulating the upper leads and the transmission line elements, the package body being disposed on the top film surface and defining a plurality of generally vertical body side surfaces which are substantially coplanar with respective ones of the film side surfaces.

14. The semiconductor package of claim 13 wherein the transmission line elements are selected from the group consisting of:
an inductor;
a shortwave coupler;
a balun;
a filter; and
combinations thereof.

15. (canceled)

16. The semiconductor package of claim 13 further comprising a plurality of pads disposed on the top film surface and electrically connected to respective ones of the upper leads, the pads being arranged in at least one set which is configured to accommodate a passive device.

17. The semiconductor package of claim 16 wherein the pads are arranged in multiple sets, each of the sets being configured to accommodate a passive device.

18. The semiconductor package of claim 13 wherein the vias are segregated into an outer set which extends along and in relative close proximity to the peripheral edge of the film layer, and an inner set which is disposed within the outer set.

19. The semiconductor package of claim 13 wherein each of the vias is lined with a conductive metal material to facilitate the electrical connection of the upper leads to respective ones of the lower leads.

20. The semiconductor package of claim 13 wherein each of the vias is filled with a conductive metal material to facilitate the electrical connection of the upper leads to respective ones of the lower leads.

21. A semiconductor package comprising:
a single non-conductive film layer defining opposed top and bottom film surfaces and a plurality of peripheral film side surfaces which extend generally perpendicularly between the top and bottom film surfaces;
a plurality of upper leads disposed on the top film surface;
a plurality of lower leads disposed on the bottom film surface, the film layer including means for electrically connecting each of the lower leads to a respective one of the upper leads;
at least one transmission line element disposed on the top film surface and electrically connected to at least one of the upper leads;
at least one semiconductor die attached to the top film surface and electrically connected to at least one of the upper leads and the transmission line element; and
a package body encapsulating the semiconductor die, the upper leads and the transmission line element, the package body being disposed on the top film surface and defining a plurality of generally vertical body side surfaces and a generally horizontal body top surface which is substantially orthogonal to the body side surfaces.
